(19) United States
(12) Patent Application Publication
(10) Pub. No.: US 2009/0160681 A1
(43) Pub. Date: Jun. 25, 2009

(54) Numeiric keyboard device with voice interaciton and the method thereof

(75) Inventors: Carrey Chen, Taipei Hsien (TW); Winnie Ku, Taipei Hsien (TW)

Correspondence Address: BACON & THOMAS, PLLC, 625 SLATERS LANE, FOURTH FLOOR, ALEXANDRIA, VA, 22314-1176, US

(73) Assignee: CHICONY ELECTRONICS CO. LTD, Taipei Hsien (TW)

(21) Appl. No.: 12/292,064

(22) Filed: Nov. 12, 2008

(30) Foreign Application Priority Data
Dec. 20, 2007 (TW) 96148872

(51) Int. Cl. H03K 17/94; G06F 15/16; G10L 21/00

(52) U.S. Cl. 341/23; 709/206; 704/275; 704/E15.001

(57) ABSTRACT

The numeric keyboard device of the present invention includes a key matrix, an audio I/O module for sending and receiving audio signals, an audio microprocessor for processing audio signals sent and received by the audio I/O module, an MCU that scans the key status of the key matrix, and a function switch that sends a first command to the key matrix to be further processed by the MCU and such that after processing said first command, the MCU sends an interrupt signal to the audio microprocessor to generate an enable signal that activates a voice interaction mode of the numeric keyboard device of the present invention.

### BACKGROUND OF THE INVENTION

1. Field of the Invention

The present invention relates to a numeric keyboard device and method for operating the same, and more particularly, to a numeric keyboard device integrated with a voice interaction function and the method thereof.

2. Description of the Related Art

With the development of digital technology and information technology, a variety of portable electronic products have become necessities in our daily life, and one of the most common electronic devices is the laptop computer. The numeric key block arranged at the right side of the desktop keyboard is usually excluded from the prior art laptop computer to make it more compact; thus, the user may insert an external numeric keypad (ten key) to the laptop computer to help perform number input and calculation tasks. Moreover, the advanced internet technology also contributes to the prosperous development of relevant telecommunication products, such as instant messaging software programs (e.g., Skype, MSN Messenger, Yahoo Messenger and Google Talk), which allow the user to send instant messages or make voice calls to other online users via the connected laptop computer. This is indeed very convenient, but an external internet phone will be required to make calls.

An external numeric keyboard device for portable electronic products generally comes with number input and calculation functions only, while an internet phone has no additional functions except for the phone function. Therefore, if one is a heavy user of the two products, s/he will need to buy both products and bring them to wherever they are needed. As this is very inconvenient for those who need to travel around all the time, the present invention endeavors to provide a solution to integrate the two products concerning the portability issue.

### SUMMARY OF THE INVENTION

An object of the present invention is to provide a numeric keyboard device integrated with a voice interaction function.

A numeric keyboard device of the present invention comprises a key matrix, an audio I/O module for sending and receiving an audio signal, an audio microprocessor for processing the audio signal sent and received by the audio I/O module, a microcontroller unit (MCU) for scanning a key status of the key matrix and a function switch for inputting a first command sent to the key matrix to be processed by the MCU such that upon the processing of said first command, the MCU sends an interrupt signal to the audio microprocessor and generates an enable signal to subsequently activate a voice interaction mode of the numeric keyboard device.

The numeric keyboard device of the present invention further includes a USB interface to connect with an electronic device installed with an internet messaging software.

The numeric keyboard device of the present invention further includes a wireless transmission interface to connect with an electronic device installed with an internet messaging software.

The electronic device described above may be a computer or PDA with a central processing unit.

The internet messaging software described above may be Skype, MSN Messenger, ICQ, Qq, Yahoo Messenger, Net2phone or Google Talk.

The numeric keyboard device of the present invention further includes an LED driver circuit electrically connected to the MCU. The MCU controls the key status to be displayed on a corresponding LED indicator according to the command sent by the function switch.

The audio I/O module described above includes at least a speaker, a microphone and a buzzer.

The numeric keyboard device of the present invention further includes an amplifier for amplifying an audio signal transmitted from the audio microprocessor to the speaker in order to output said audio signal, and for amplifying another audio signal inputted from the microphone and transmitted to the audio microprocessor.

The function switch corresponds to a switch key. The corresponding switch key is designed as a shortcut key or set as a default key with the use of software.

Further, the function switch is used for inputting a second command that is sent to the key matrix to be processed by the MCU, such that after the processing of said second command, the MCU sends an interrupt signal to the audio microprocessor and generates a disable signal to subsequently return to a keyboard mode.

Another objective of the present invention is to provide an advanced numeric keyboard device integrating a known numeric keyboard device having the mere functions of numerical inputs and calculations with a voice interaction function including the one of internet phone. The present invention integrates the voice interaction function into a numeric keyboard device, and thus reduces the manufacturing cost by means of hardware resource sharing. The numeric keyboard device of the present invention adopts a switch key that allows the user to switch between the voice interaction mode and keyboard mode swiftly.

The technical features of the present invention will be described more fully hereinafter with reference to the accompanying drawings, in which preferred embodiments of the invention are shown. It is to be understood that the accompanying drawings and embodiments are provided so that this disclosure will fully convey the scope of the invention, and this invention should not be construed as limited to the embodiments set forth herein.

### BRIEF DESCRIPTION OF THE DRAWINGS

FIG. 1 is a block diagram showing a numeric keyboard device of the present invention;

FIG. 2 is a schematic view showing the exterior of the numeric keyboard device of the present invention; and

FIG. 3 is a flow chart showing the operation process of the numeric keyboard device of the present invention.

### DETAILED DESCRIPTION OF THE PREFERRED EMBODIMENTS

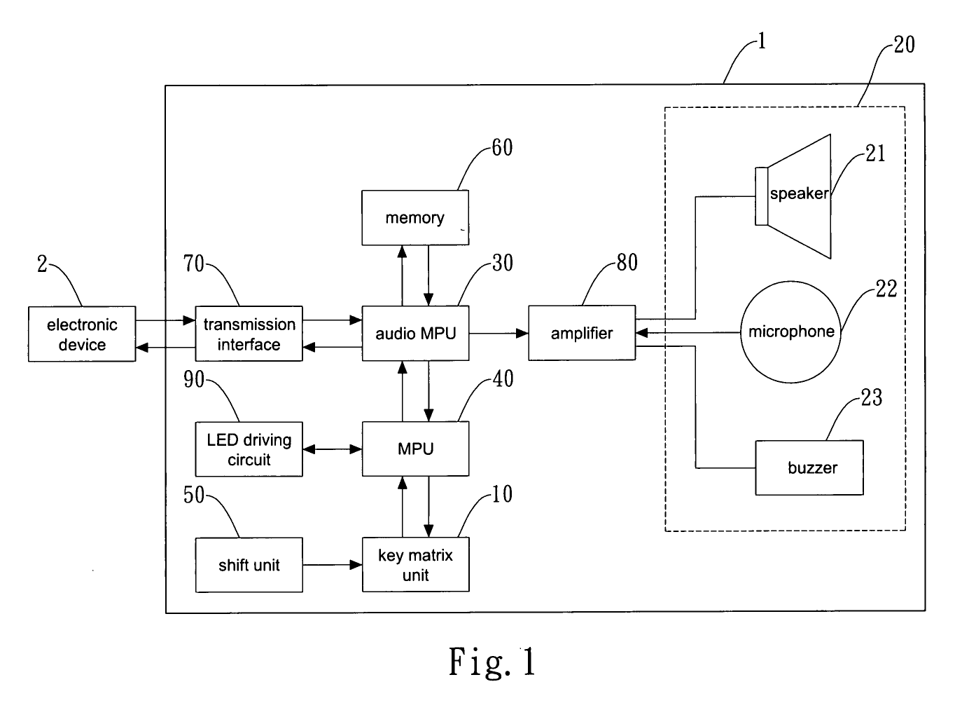

FIG. 1 is a block diagram showing a numeric keyboard device of the present invention. The numeric keyboard device 1 comprises a key matrix 10 including at least a numeric key, an audio I/O module 20 for sending and receiving an audio signal, an audio microprocessor 30 for processing the audio signal sent and received by the audio I/O module 20, a microcontroller unit (MCU) 40 capable of scanning a key status of the key matrix 10, and a function switch 50 that may send a first or a second command to the key matrix 10 in response to an input from a user acted thereon. In one embodiment of the present invention, the numeric keyboard device 1 includes at least two modes, a voice interaction mode and a keyboard mode, controlled by said MCU 40 depending upon the signals generated thereon and transmitted from said function switch 50. If the key matrix 10 receives a first command, after processing the first command, the MCU 40 generates an interrupt signal which is then sent to the audio microprocessor 30 and generates an enable signal that subsequently activates the voice interaction mode. If the key matrix 10 receives a second command, after processing the second command, the MCU 40 generates an interrupt signal to the audio microprocessor 30 and generates a disable signal that subsequently allows the numeric keyboard device 1 to return to the keyboard mode of the numeric keyboard device 1.

The numeric keyboard device 1 of the present invention may further include a memory 60 for storing program data and accessing the audio signal sent and received by the audio microprocessor 30. The numeric keyboard device 1 may still include a transmission interface 70, which may be a USB interface or wireless transmission interface, for connecting with an electronic device 2 that is connected to the internet (not shown in the diagram) and installed with an internet or instant messaging software. When the numeric keyboard device 1 is switched to the voice interaction mode through the function switch 50, it can activate the instant messaging software installed in the connected electronic device 2 via the transmission interface 70 (USB or wireless) to communicate with other remote users.

The electronic device 2 may be a personal computer with a central processing unit/CPU, PDA or any portable electronic product while the internet or instant messaging software may be selected from the following software programs of Skype, MSN Messenger, ICQ, Qq, Yahoo Messenger, Net2phone or Google Talk.

In one embodiment, the audio I/O module 20 includes a speaker 21, a microphone 22 and a buzzer 23. The speaker 21 and microphone 22 allow the user to take and make phone calls and the buzzer 23 informs the user of the incoming internet calls when the numeric keyboard device 1 is switched to the voice interaction mode.

The numeric keyboard device 1 also includes an amplifier 80 that amplifies audio signals transmitted from the audio microprocessor 30 to the speaker 21 to output an audio signal, and audio signals inputted from the microphone 22 may be amplified and sent to the audio microprocessor 30.

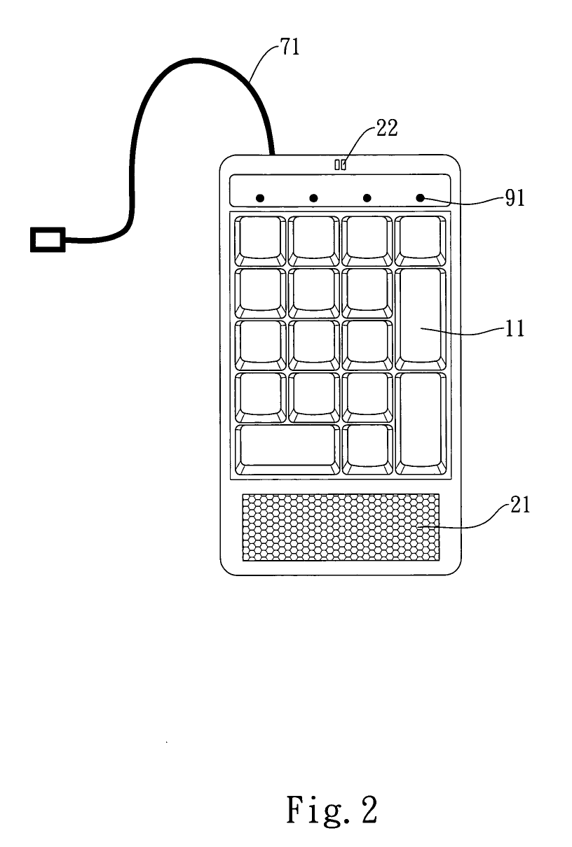

The numeric keyboard device 1 further includes an LED driver circuit 90 electrically connected to the MCU 40. The MCU 40 controls the corresponding key status, voice interaction mode or keyboard mode, to be displayed on an LED indicator according to the command sent to the key matrix 10 by the function switch 50 (please refer to FIG. 2).

The function switch 50 may correspond to a switch key that may be pressed to switch between the voice interaction mode and keyboard mode. Said corresponding switch key may be a built-in switch key of said key matrix 10 and it can too be designed as a shortcut key or set as a default key with the use of software. In addition, said switch key may be a “Shift” key corresponding to the key matrix 10.

FIG. 2 is a schematic view showing the exterior of the numeric keyboard device of the present invention. In this embodiment, the numeric keyboard device 1 is connected to an electronic device 2 through a port 71, which may be a USB port or LAN port, and the corresponding keys 11 of the key matrix 10 include digits keys (0˜9), arithmetic keys (+, −, × and /) and other keys including Num Lock, Enter, Del and etc.

A plurality of LED indicators 91 are set above the corresponding keys 11 of the key matrix 10 to indicate the key status: voice interaction mode or keyboard mode. The microphone 22 located above the LED indicators 91 and the speaker 21 located below the corresponding keys 11 are used to input and output audio signals respectively under the voice interaction mode.

When the user attempts to make an internet call with the numeric keyboard device 1 of the present invention, s/he can connect it, through the USB port, LAN port or wireless transmission interface, to an electronic device 2 that is connected to the internet and installed with instant messaging software. After that, the corresponding switch key of the function switch 50 can be pressed to send a first command to the key matrix 10 to be further processed by the MCU 40. After processing, the MCU 40 has an interrupt signal sent to the audio microprocessor 30 for generating an enable signal that activates the voice interaction mode; meanwhile, the internet/instant messaging software installed in the electronic device 2, which is connected to the internet, may be activated. The user can then dial the phone number, using the corresponding keys 11 of the key matrix 10, to make an internet call that relies on the speaker 21 and the microphone 22 to output and input audio signals respectively. The numeric keyboard device 1 of the present invention may then automatically return to the keyboard mode shortly after the call ends. In addition, the corresponding switch key of the function switch 50 can also be pressed to send a second command to the key matrix 10 to be further processed by the MCU 40. After processing said second command, likewise, the MCU 40 generates an interrupt signal sent to the audio microprocessor 30 to generate a disable signal allowing the numeric keyboard device 1 to return to the keyboard mode after the call ends.

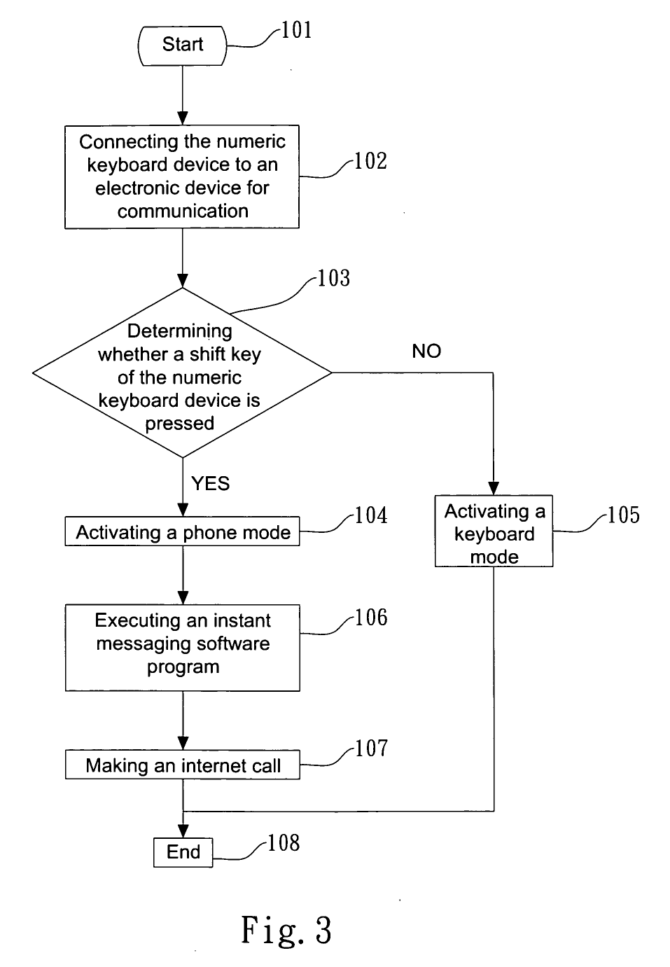

FIG. 3 is a flow chart showing the operation process of the numeric keyboard device of the present invention. As illustrated in the flow chart, at step 101, the user starts to use the numeric keyboard device 1; at step 102, the numeric keyboard device 1 is connected to an electronic device 2, which is connected to the internet and installed with instant messaging software, through a USB port, LAN port or wireless transmission interface; at step 103, the numeric keyboard device 1 decides whether the corresponding switch key of the function switch 50 is pressed or not, and the process will proceed to step 104 if the switch key is pressed, otherwise it will proceed to step 105; at step 104, after the MCU 40 has scanned the key status of the switch key, an interrupt signal is sent to the audio microprocessor 30 to generate an enable signal that activates the voice interaction mode; at step 105, the keyboard mode is activated as the switch key has not been pressed; at step 106, the instant messaging software installed in the electronic device 2 that is connected to the internet is executed at the same time when the voice interaction mode is activated; at step 107, the user can make an internet call to a remote user by using the corresponding keys 11 of the key matrix 10 to dial the phone number; at step 108, the corresponding keys of the key matrix 10 return to the keyboard mode after the call ends.

After the call ends at step 108, the corresponding switch key of the function switch 50 can be pressed again to send a command to the key matrix 10 and further processed by the MCU 40. After processing said command, the MCU 40 sends an interrupt signal to the audio microprocessor 30 and generates a disable signal that enables the numeric keyboard device 1 to return to the keyboard mode. As one having ordinary skill in the art can well comprehend and accomplish such operation after step 108, no additional drawings and descriptions will be provided hereafter.

The numeric keyboard device of the present invention that features the voice interaction function effectively integrates the hardware design for direction control of a keyboard and of an internet phone. By utilizing a switch key allowing a user to conveniently switch between the voice interaction function and keyboard function, the present invention may greatly reduce the hardware parts and components involved to achieve claimed effects and may, at the same time, significantly reduced the costs and materials as in terms of both the manufacturer and the end-user perspectives.

In conclusion, the numeric keyboard device of the present invention utilizes a numeric keyboard device integrated with a voice interaction function allowing a user to switch between a voice interaction mode and a keyboard mode automatically and/or selectively via a switch key, such convenient design is not only novel but may also reduce the redundancy of hardware parts and components which may in term significantly save costs and resources as in terms of both the manufacturer and the end-users.

While this invention has been described by way of examples and in terms of preferred embodiments, it is to be understood that this invention is not limited hereto, and that various changes, substitutions, and alterations can be made herein without departing from the spirit and scope of this invention as defined by the appended claims. For example, the numeric keyboard device of the present invention can be equipped with a webcam to acquire the video conference function.

What is claimed is:

1. A numeric keyboard device with a voice interaction function, comprising:
a key matrix;
an audio I/O module for sending and receiving an audio signal;
an audio microprocessor for processing the audio signal sent and received via said audio I/O module;
an MCU for scanning a key status of said key matrix; and
a function switch for inputting a first command sent to said key matrix and processed by said MCU and such that upon processing said first command, the MCU sends an interrupt signal to said audio microprocessor and generates an enable signal to subsequently activate a voice interaction mode of said numeric keyboard device.

2. The numeric keyboard device with a voice interaction function according to claim 1, further comprising a USB interface to connect with an electronic device installed with an internet messaging software.

3. The numeric keyboard device with a voice interaction function according to claim 1, further comprising a wireless transmission interface to connect with an electronic device installed with an internet messaging software.

4. The numeric keyboard device with a voice interaction function according to claim 2, wherein said electronic device is a personal computer with a central processing unit.

5. The numeric keyboard device with a voice interaction function according to claim 2, wherein said internet messaging software is selected from at least one of the following programs: Skype, MSN Messenger, ICQ, Qq, Yahoo Messenger, Net2phone and Google Talk.

6. The numeric keyboard device with a voice interaction function according to claim 1, further comprising an LED driver circuit electrically connected to said MCU said MCU controlling said key status to be displayed on a corresponding LED indicator in response to said first command of the function switch.

7. The numeric keyboard device with a voice interaction function according to claim 1, wherein said audio I/O module includes at least a speaker, a microphone and a buzzer.

8. The numeric keyboard device with a voice interaction function according to claim 7, further comprising an amplifier for amplifying an audio signal transmitted from said audio microprocessor to said speaker in order to output said audio signal, and for amplifying another audio signal inputted from said microphone and transmitted to said audio microprocessor.

9. The numeric keyboard device with a voice interaction function according to claim 1, wherein said function switch corresponds to a built-in switch key of said key matrix.

10. The numeric keyboard device with a voice interaction function according to claim 9, wherein said switch key is set as a shortcut key with the use of software.

11. The numeric keyboard device with a voice interaction function according to claim 1, wherein said function switch further inputs a second command sent to said key matrix and processed by said MCU and such that upon processing said second command, the MCU sends an interrupt signal to said audio microprocessor and generates a disable signal to subsequently return to a keyboard mode of said numeric keyboard device.

12. A method of a numeric keyboard device with a voice interaction function according to claim 1, comprising the steps of:
(1) connecting said numeric keyboard device to an electronic device for communication;
(2) determining whether a function switch of said numeric keyboard device is pressed, and proceeding to step (3) if said function switch is pressed or proceeding to step (4) if said function switch is not pressed;
(3) activating a voice interaction mode and proceeding to step (5);
(4) activating a keyboard mode of said numeric keyboard device;
(5) executing an internet messaging program and then proceeding to step (6);
(6) creating an internet call and then proceeding to step (7); and
(7) ending the internet call and returning to the keyboard mode of said numeric keyboard device.

13. The method according to claim 12, wherein at step (3) a function switch is used for inputting a first command that is sent to said key matrix to be processed by said MCU and such that upon processing said first command, the MCU sends an interrupt signal to said audio microprocessor and generates an enable signal to subsequently activate a voice interaction mode of said numeric keyboard device.

14. The method according to claim 12, further including the step of returning to the keyboard mode of said numeric keyboard device by further pressing the function switch.

15. The method according to claim 12, wherein during said step of returning to the keyboard mode of said numeric keyboard device, said function switch is pressed to input a second command to said key matrix and processed by said MCU and such that upon processing said second command, the MCU sends an interrupt signal to said audio microprocessor and generates a disable signal to subsequently return to the keyboard mode of the numeric keyboard device.
